(19) United States
(12) Patent Application Publication
(10) Pub. No.: US 2022/0130904 A1
(43) Pub. Date: Apr. 28, 2022

(54) BURIED TRACK

(71) Applicant: STMICROELECTRONICS (ROUSSET) SAS, Rousset (FR)

(72) Inventor: Philippe BOIVIN, Venelles (FR)

(73) Assignee: STMICROELECTRONICS (ROUSSET) SAS, Rousset (FR)

(21) Appl. No.: 17/507,624

(22) Filed: Oct. 21, 2021

(30) Foreign Application Priority Data
Oct. 23, 2020 (FR) 2010895

(51) Int. Cl. H01L 27/24; H01L 45/00

(52) U.S. Cl. CPC H01L 27/2463; H01L 45/1683; H01L 45/06

(57) ABSTRACT

The present description concerns a method of forming a track in a first layer, including a) forming a cavity in the first layer; b) totally filling the cavity with a first material; and c) partially removing the first material from the upper portion of the cavity, to form the track made of the first material.

### BACKGROUND

### Technical Field

The present disclosure generally concerns electronic devices and more particularly devices comprising tracks and their manufacturing methods.

### Description of the Related Art

Electronic device manufacturing methods generally comprise two distinct phases.

A first phase, called “Front-End-Of-Line” (FEOL), comprises the forming of semiconductor components inside and on top of a substrate, in particular transistors, capacitive elements, resistors, etc. The first phase also comprises the forming of other elements in the substrate, in particular insulating walls for example separating components.

A second phase, called “Back-End-Of-Line” (BEOL), comprises the forming of the interconnects between components. In particular, the second phase comprises the forming, on the substrate, of a stack of conductive tracks and of insulating layers crossed by conductive vias, the conductive vias coupling the conductive tracks.

The interconnects, formed during the BEOL phase, are highly area-consuming. In particular, the conductive track levels closest to the substrate, for example, M1, M2, and M3, are the thickest and the most constraining.

### BRIEF SUMMARY

An embodiment overcomes all or part of the disadvantages of known tracks.

An embodiment provides a method of manufacturing a track in a first layer, comprising:
a) forming a cavity in the first layer;
b) totally filling the cavity with a first material; and
c) partially removing the first material from the upper portion of the cavity, to form said track made of said first material.

According to an embodiment, the track is present at least in the bottom of the cavity.

According to an embodiment, the semiconductor layer is made of semiconductor material.

According to an embodiment, the method comprises forming electronic components inside and on top of the first layer.

According to an embodiment, the method comprises forming phase-change memory cells on the first layer.

According to an embodiment, the first material is a conductive or semiconductor material.

According to an embodiment, the first material is an insulating material.

According to an embodiment, the method comprises between steps a) and b), a step d) of forming of a second insulating layer on the walls and the bottom of the cavity.

According to an embodiment, the method comprises, between steps d) and b), a step e) of removal of the portion of the second layer located on the bottom of the cavity.

According to an embodiment, step e) is an anisotropic etching of the material of the second layer.

According to an embodiment, the method comprises, after step c), a step f) of removal of the second layer from the cavity.

According to an embodiment, the method comprises, after step f), a step g) of filling of the cavity with the material of the first layer.

According to an embodiment, step g) comprises, in the cavity, an epitaxial growth of the material of the first layer.

According to an embodiment, the method comprises, after step c), filling the cavity with an insulating material.

Another embodiment provides an electronic device comprising a buried track obtained by the previously-described method.

Another embodiment provides an electronic device comprising a track made of a first material buried in a first layer.

According to an embodiment, phase-change memory cells are formed on the first layer.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 shows an interconnection track forming step;

FIG. 2 shows another interconnection track forming step;

FIG. 3 shows another interconnection track forming step;

FIG. 4 shows another interconnection track forming step;

FIG. 5 shows another interconnection track forming step;

FIG. 6 shows a step of a variant of the steps of FIGS. 1 to 5;

FIG. 7 shows another step of the variant of the method of FIGS. 1 to 5;

FIG. 8 shows another step of the variant of the method of FIGS. 1 to 5; and

FIG. 9 shows another step of the variant of the method of FIGS. 1 to 5.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

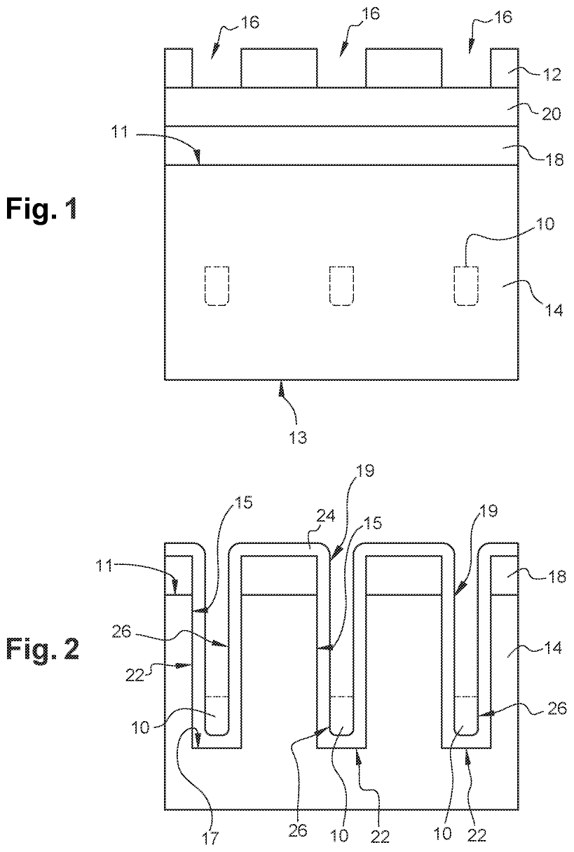

FIGS. 1 to 5 show steps, preferably successive, of an implementation mode of a method of manufacturing buried tracks, preferably interconnection tracks, or conductive tracks. The steps described in relation with FIGS. 1 to 5 are for example steps implemented in the “Front-End-Of-Line” (FEOL) electronic device manufacturing phase.

FIG. 1 shows a buried interconnection track forming step. Locations 10, shown in dotted lines, correspond to the desired locations of the interconnection tracks.

Locations 10 are buried in a layer 14. Buried means located at least 50 nm away from the surface closest to layer 14, for example, from the upper surface 11, preferably located from 50 nm to 1,000 nm away from the surface closest to layer 14. The depth of the locations of the interconnection tracks may be selected according to the applications.

Layer 14 is preferably a semiconductor substrate, for example, made of silicon. Preferably, electronic components such as transistors, capacitive elements, resistors, etc., will be formed inside and on top of substrate 14. Preferably, components such as memory cells may be formed on substrate 14. The conductive tracks for example extend between at least two electronic components so as to connect them. Preferably, the conductive tracks extend between doped regions forming component portions. For example, the conductive tracks extend between drain or source regions of a plurality of transistors to couple them.

A lower surface 13 of the substrate 14 is opposite to the upper surface 11 of the substrate 14.

As a variant, layer 14 may be made of another material, for example, an insulating material.

During the step of FIG. 1, an etch mask 12 is formed on layer 14. Mask 12 comprises openings 16. Openings 16 are located opposite locations 10, in layer 14, where the buried conductive tracks are desired to be formed. Each opening 16 is aligned with and overlaps a corresponding one of the locations 10. Preferably, openings 16 have horizontal dimensions greater than the horizontal dimensions of the conductive tracks which are desired to be formed, so that the desired locations 10 of the conductive tracks are entirely opposite openings 16.

Preferably, mask 12 is separated from the upper surface 11 of layer 14, that is, the surface 11 of layer 14 closest to the mask 12, by two layers 18 and 20 of insulating material. Layer 18 rests on the upper surface of layer 14. Preferably, layer 18 is in contact with the upper surface 11 of layer 14. Layer 18 is preferably made of silicon nitride. Layer 20 rests on layer 18. Preferably, layer 20 is in contact with layer 18. Layer 20 is preferably made of silicon oxide. Mask 12 rests on layer 20. Preferably, mask 12 is in contact with layer 20.

Preferably, the thickness of layer 18 is smaller than the thickness of layer 14. Preferably, the thickness of layer 18 is smaller than 100 nm. Preferably, the thickness of layer 20 is smaller than the thickness of layer 14. Preferably, the thickness of layer 20 is smaller than 100 nm. Preferably, the thickness of layer 14 is greater than 500 nm.

FIG. 2 shows another interconnection track forming step.

During this step, layers 14, 18, and 20 are etched via the openings 16 of the etch mask, to form cavities 22. Cavities 22 reach at least the depth of the locations 10 of the interconnection tracks. Thus, the portions of layer 14 located at locations 10 are totally removed. In the example of FIG. 2, cavities 22 extend deeper than the level of locations 10. Preferably, the etch mask and layer 20 (FIG. 1) are then removed.

A layer 24 made of an insulating material is then conformally formed on the structure. Layer 24 thus covers the walls 15 and a surface 17 of the substrate 14. The surfaces of the substrate 14 partially delimit the cavities 22 and are at the ends of the cavities 22. The walls 15 may include sidewall surfaces of the layer 14 and the layer 18 that are substantially coplanar with each other. Layer 24 enables to protect layer 14, in particular when layer 14 is made of a semiconductor material, during the next interconnection track forming steps. Layer 24 is preferably made of silicon oxide. The thickness of layer 24 is for example smaller than 50 nm, preferably smaller than 20 nm. The thickness of layer 24 is such that layer 24 does not fill cavities 22. A cavity 26 is thus formed in each cavity 22, the walls and the bottoms of cavities 26 being formed by layer 24. The cavity 26 may be a sub-cavity of the cavity 22 partially delimited by the layer 24. The layer 24 includes walls 19 that are overlapping the walls 15 partially delimiting the cavities 22.

The dimensions of cavities 22 and of layer 24 are selected so that layer 24 is not formed at locations 10. Locations 10 each form the lower portion of a cavity 26. Layer 24 thus forms, in each cavity 22, a portion of the contour of location 10. The lateral and lower contours of each location 10 are thus separated from the walls of cavity 22 by a distance substantially equal to the thickness of layer 24.

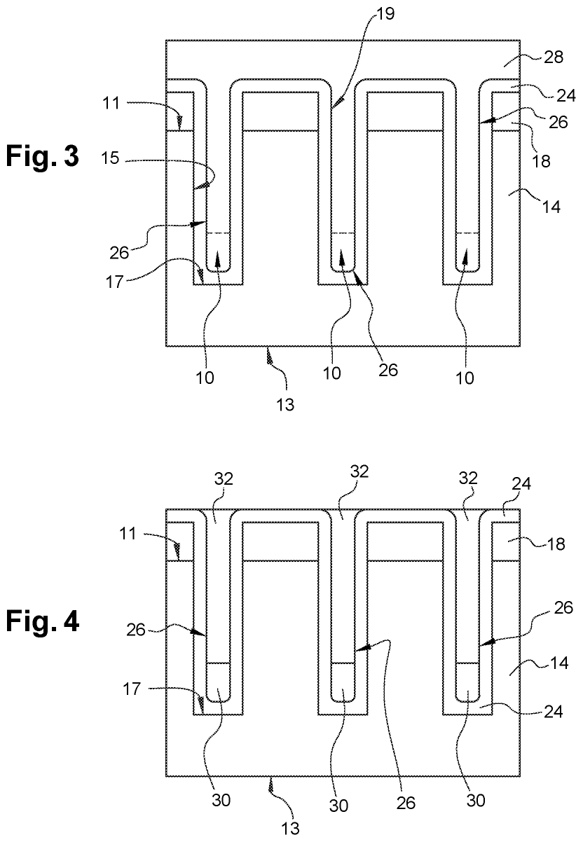

FIG. 3 shows another interconnection track forming step.

During this step, a layer 28 is formed on the structure. Layer 28 entirely fills cavities 26. In other words, layer 28 entirely fills cavities 26. In particular, layer 28 entirely fills locations 10.

The material of layer 28 is the material of the interconnection tracks. The material of layer 28 is thus preferably a material allowing an electric connection. The material of layer 28 is a conductive or semiconductor material. The material of layer 28 is, for example, carbon or silicon.

As a variant, the track is not an interconnection track but an insulating track, for example, forming an insulating wall. Layer 28 is then for example made of an insulating material, for example, of an electrically-insulating material based on silicon, for example, of silicon oxide or of silicon nitride. The material of layer 28 is however made of a material different from the material of layer 24. The material of layer 28 is made of a material different from the material of layer 14.

FIG. 4 shows another interconnection track forming step.

During this step, layer 28 is etched to remove the portions of layer 28 located outside of locations 10. Interconnection tracks 30 are thus formed at the bottom of cavities 26, at locations 10. Preferably, at least half of the material of layer 28 located in each cavity 26 is removed. The material of layer 28 is thus removed from the upper portion of each cavity 26, that is, from the portion closest to the opening of each cavity 26. The upper portion of each cavity preferably corresponds to at least the upper half of the cavity.

Cavities 26 are then filled, preferably totally, with portions 32 made of an insulating material, for example, of an electrically-insulating material based on silicon, for example, of silicon oxide or of silicon nitride. Portions 32 for example extend from tracks 30 and all the way to at least the level of the upper surface of layer 14.

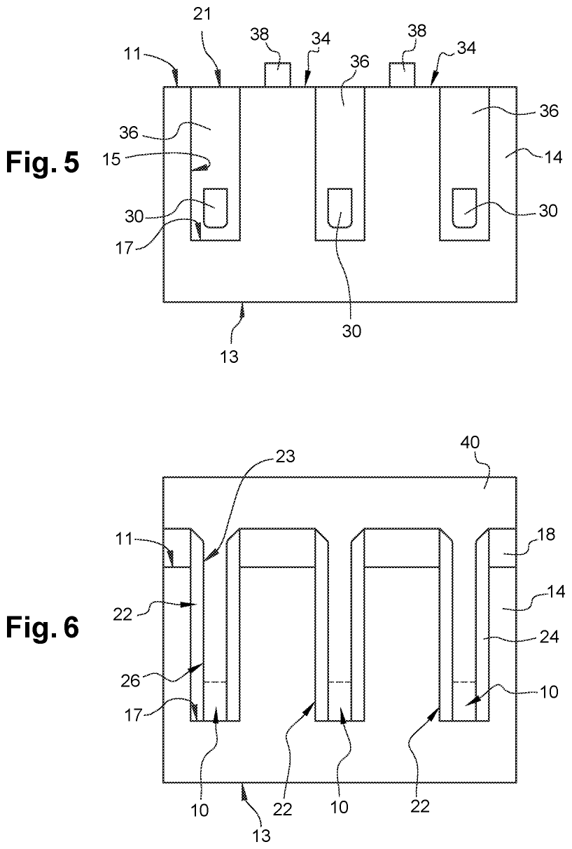

FIG. 5 shows another interconnection track forming step. Further, FIG. 5 shows an application of the interconnection tracks obtained according to the method of FIGS. 1 to 4.

The step of FIG. 5 comprises an etch step. The etch step is preferably configured to expose portions 34 of layer 14 located between cavities 26 (FIG. 4). Preferably, the etch step removes layer 18 and removes the portions of layer 24 and of the material of portions 32 located above the level of the upper surface of layer 14.

Interconnection tracks 30 are thus located in insulating portions 36 extending from the upper surface 11 of layer 14. Conductive tracks 30 are buried in layer 14. Insulating portions 36 for example form insulating walls separating electronic components formed inside and on top of portions 34. In the example of FIG. 5, a transistor, represented by its gate 38, is formed inside and on top of each portion 34.

The insulating portions 36 may have a surface 21 facing away from the conductive track 30. The surface 21 may be substantially coplanar and substantially flush with the surface 11 of the substrate 14.

Tracks 30 such as described in relation with FIGS. 1 to 5 may for example be used as voltage rails. In other words, said tracks may be coupled to a source of a voltage, for example, of a power supply voltage.

FIGS. 6 to 9 show steps, preferably successive, of an alternative implementation mode of the method of FIGS. 1 to 5. These steps are carried out after the steps described in relation with FIGS. 1 and 2. However, the step of FIG. 2 comprised in the alternative implementation mode of FIGS. 6 to 9 differs from the step described in relation with FIG. 2 in that the bottom of each cavity 22 preferably corresponds to the bottom, that is, to the portion most distant from the upper surface of layer 14, of the corresponding location 10.

FIG. 6 shows a step of an alternative implementation mode of the method of FIGS. 1 to 5.

The step of FIG. 6 comprises a step of partial anisotropic-type etching of layer 24. Thus, the portions of layer 24 located at the bottom of cavities 22 and on the upper surface of layer 18 are removed. The portions of layer 24 located on the walls of cavities 22 are not removed by the etching.

The step also comprises the forming of a layer 40 over the entire structure. Layer 40 entirely fills cavities 26. Cavities 26 are thus totally filled with layer 40. In particular, layer 40 entirely fills locations 10. The layer 40 covers walls 23 of the layer 24, and the walls 23 extend away from the surfaces 17 of the substrate 14.

The material of layer 40 is the material of the interconnection tracks. The material of layer 40 thus is a material allowing an electric connection. The material of layer 40 is a conductive or semiconductor material. The material of layer 40 is for example carbon or silicon.

As a variant, the track is not an interconnection track but an insulating track, for example forming an insulating wall. Layer 40 is then for example made of an insulating material, for example, of an electrically-insulating material based on silicon, for example, of silicon oxide or of silicon nitride. The material of layer 40 is however made of a material different from the material of layer 24. The material of layer 40 is a material different from layer 14.

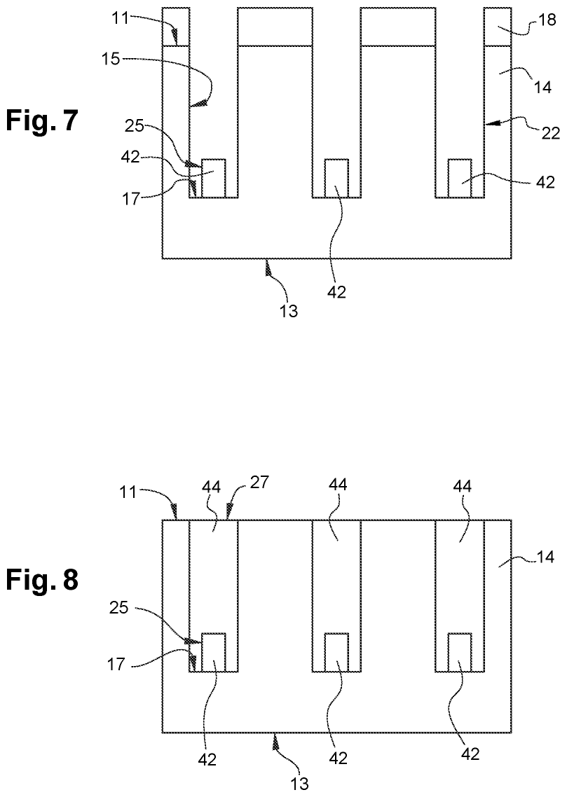

FIG. 7 shows another step of a variant of the method of FIGS. 1 to 5.

During this step, the portions of layer 40 located outside of the locations 10 of the conductive tracks are removed. Interconnection tracks 42 are thus formed at the bottom of cavity 22.

The portions of layer 24 located on the walls of cavities 22 are then removed. Thus, tracks 42 are not in contact with the lateral walls of cavities 22. The tracks have sidewall 25 that are transverse to the surfaces 17 of the substrate 14.

FIG. 8 shows another step of a variant of the method of FIGS. 1 to 5.

During this step, cavities 22 are preferably filled with portions 44 made of the material of layer 14. Preferably, portions 44 are formed by epitaxial growth. Portions 44 preferably grow in cavities 22 from layer 14. The portions 44 cover the sidewalls 25 of the tracks 42. The portions 44 have a surface 27 substantially coplanar and substantially flush with the surface 11 of the substrate 14.

As a variant, each cavity 22 may be filled with an insulating material.

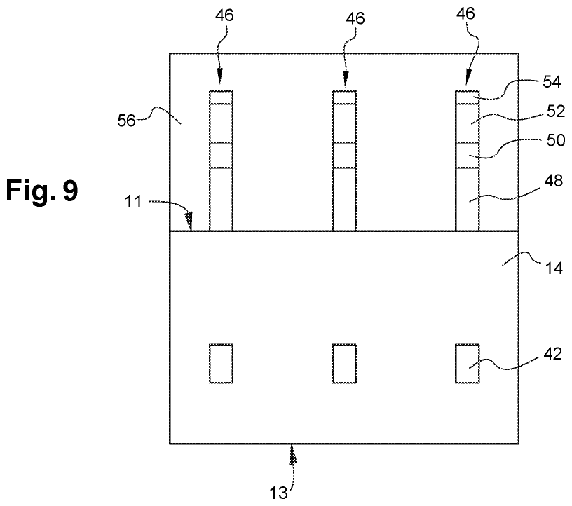

FIG. 9 shows another step of an alternative implementation mode of the method of FIGS. 1 to 5. More particularly, FIG. 9 shows an application of the interconnection tracks obtained by the embodiment of FIGS. 6 to 9.

In this example of application, interconnection tracks 42 are each located under a memory cell 46, for example, a phase-change memory cell. Memory cells 46 are for example formed after the step of FIG. 8.

Each phase-change memory cell 46 comprises a via 48, a resistive element 50, a layer 52 of a phase-change material, and an electrode 54, stacked in this order from the upper surface of the substrate.

The phase-change memory cells 46 are covered by a layer 56. The layer 56 may be formed such that the phase-change memory cells 46 are embedded within the layer 56.

As a variant, the steps described in relation with FIGS. 1 to 5 and the steps described in relation with FIGS. 6 to 9 may be implemented in the BEOL phase. In the BEOL phase, the steps are for example carried out on the surface opposite to the surface of the substrate having components formed on top and inside thereof. The conductive or semiconductor material of the conductive tracks depends on the thermal budget of the method. Thus, if the steps are carried out during the BEOL phase, tracks 30 and 42 are for example made of metal.

As a variant, layer 14 may be made of a material other than a semiconductor material. For example, layer 14 may be made of an insulating material, covering for example a portion of a semiconductor substrate.

As a variant, the material of the layer 28 of the implementation mode of FIGS. 1 to 5, and the material of the layer 40 of the variant of FIGS. 6 to 9, is for example made of a thermally refractory material, preferably formed based on silicon, for example, a silicide. Preferably, the steps described in relation with FIGS. 1 to 5 and the steps described in relation with FIGS. 6 to 9 are carried out after the manufacturing steps having a high thermal budget, to avoid the expansion of the materials of layer 28 or of layer 40. For example, the steps described in relation with FIGS. 1 to 5 and the steps described in relation with FIGS. 6 to 9 are carried out just before the forming of electric contacts on layer 14.

An advantage of the described embodiments is that it is possible to form buried electric links. This enables to save space which would be used to form conductive vias. Thus, it is possible to form local links, without forming conductive track levels M1, M2, and M3.

An advantage of the embodiments of FIGS. 6 to 9 is that it is possible to form connections between the transistors under the memory cells. It could have been chosen to couple the components with vias and conductive tracks located above the cells. However, spaces would have had to be provided between certain cells for vias or connection strips. In the embodiment of FIGS. 6 to 9, this space may be used for memory cells.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

Method of forming a track (30, 42) in a first layer (14), may be summarized as including a) forming a cavity (22) in the first layer (14); b) totally filling the cavity (22) with a first material (28, 40); and c) partially removing the first material from the upper portion of the cavity (22), to form said track made of said first material.

The track may be present at least in the bottom of the cavity (22).

The first layer (14) may be made of a semiconductor material.

The first layer (14) may be made of an insulating material.

Method may include forming electronic components (38) inside and on top of the first layer (14).

Method may include forming phase-change memory cells on the first layer (14).

The first material (28, 40) may be a conductive or semiconductor material.

The first material may be an insulating material.

Method may include between steps a) and b), a step d) of forming of a second insulating layer on the walls and the bottom of the cavity (22).

Method may include, between steps d) and b), a step e) of removal of the portion of the second layer (24) located on the bottom of the cavity (22).

Step e) may be an anisotropic etching of the material of the second layer (24).

Method may include, after step c), a step f) of removal of the second layer (24) from the cavity (22).

Method may include, after step f), a step g) of filling of the cavity with the material of the first layer (14)

Step g) may include, in the cavity (22), an epitaxial growth of the material of the first layer.

Method may include, after step c), filling the cavity with an insulating material.

Electronic device may be summarized as including a buried track obtained by the method.

Electronic device may be summarized as including a buried track (30, 42) made of a first material in a first layer (14).

Phase-change memory cells (46) are arranged on the first layer.

The first layer (14) may be made of a semiconductor material.

The first layer (14) may be made of an insulating material.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a cavity extending into a layer on a first surface of a substrate, extending into a first surface of the substrate, and terminating at an end within the substrate before reaching a second surface of the substrate opposite to the first surface;
filling the cavity including:
forming a first insulating material on the layer, overlapping the first surface of the substrate, partially filling a first portion of the cavity with the first insulating material covering walls of the layer and the substrate extending away from the end to the first surface of the substrate;
partially filling a second portion of the cavity with a conductive material covering walls of the first insulating material;
forming a conductive track by partially removing the conductive material from the cavity.

2. The method according to claim 1, wherein forming the conductive track further includes forming the track adjacent to the end of the cavity.

3. The method according to claim 1, wherein forming the insulating layer further includes:
covering a surface of the substrate at the end of the cavity and transverse to the walls of the substrate.

4. The method according to claim 1, wherein partially filling the second portion of the cavity with the conductive material further includes:
covering a surface of the substrate at the end of the cavity and transverse to the walls of the substrate.

5. The method according to claim 1, further comprising forming electronic components on the first surface of the substrate.

6. The method according to claim 5, wherein forming the electronic components includes forming phase-change memory cells on the first surface of the substrate.

7. The method according to claim 6, wherein forming the phase-change memory cells on the first surface of the substrate includes:
forming a via extending from the first surface of the substrate;
forming a resistive element on the via;
forming a phase-change material on the resistive element; and
forming an electrode on the phase-change material.

8. The method according to claim 6, further comprising forming a layer of material covering the phase-change elements.

9. The method according to claim 1, further comprising removing a portion of the insulating layer located at the end of the cavity.

10. The method according to claim 9, wherein removing the portion of the insulating layer located at the end of the cavity further includes anisotropically etching the insulating layer.

11. The method according to claim 9, further comprising removing the insulating layer from the walls of the layer, the walls of the substrate, and the cavity.

12. The method according to claim 11, further comprising filling the cavity with a material selected from a semiconductor material and a second insulating material.

13. The method according to claim 12, wherein filling the cavity includes epitaxially growing the material selected from the semiconductor material and the second insulating material.

14. The method according to claim 1, further comprising filling the cavity with a second insulating material covering the conductive track.

15. A device, comprising:
a substrate having a first surface, a second surface opposite to the first surface, a third surface between the first surface and the second surface, and a first wall that extends into the first surface to the third surface;
a first insulating portion in the substrate covering the first wall and the third surface;
a first buried conductive track encased by the first insulating portion, the first buried conductive track spaced apart from the third surface of the substrate by the first insulating portion.

16. The device of claim 15, further comprising a transistor at the first surface of the substrate.

17. The device of claim 15, further comprising:
a second insulating portion in the substrate spaced apart from the first insulating portion;
a second buried conductive track encased by the second insulating portion, the second buried conductive track spaced apart from the substrate by the second insulating portion,

18. The device of 17, further comprising a transistor at the first surface, the transistor is between the first insulating portion and the second insulating portion, and the transistor is between the first buried conductive track and the second buried conductive track.

19. A device, comprising:
a substrate having a first surface, a second surface opposite to the first surface, a third surface between the first surface and the second surface, and a wall that extends into the first surface to the third surface;
a first insulating portion in the substrate covering the wall and partially covering the third surface;
a first buried conductive track within the first insulating portion, the first buried conductive track in contact with the third surface of the substrate, the first buried conductive track spaced apart from the wall of the substrate by the first insulating portion, and the first buried conductive track including a sidewall covered by the first insulating portion.

20. The device of claim 19, further comprising:
a second insulating portion in the substrate spaced apart from the first insulating portion;
a second buried conductive track within the second insulating portion, the second buried conductive track in contact with the substrate.
